(19) United States
(12) Patent Application Publication
(10) Pub. No.: US 2014/0339581 A1
(43) Pub. Date: Nov. 20, 2014

(54) METHOD OF MANUFACTURING SEMICONDUCTOR LIGHT EMITTING DEVICE PACKAGE

(71) Applicants: Yong Min KWON, Seoul (KR); Hak Hwan KIM, Suwon-si (KR); Min Young SON, Seoul (KR); Sung Jun IM, Yongin-si (KR)

(72) Inventors: Yong Min KWON, Seoul (KR); Hak Hwan KIM, Suwon-si (KR); Min Young SON, Seoul (KR); Sung Jun IM, Yongin-si (KR)

(21) Appl. No.: 14/274,497

(22) Filed: May 9, 2014

(30) Foreign Application Priority Data
May 14, 2013 (KR) 10-2013-0054234

(51) Int. Cl. H01L 33/64; H01L 33/50; H01L 33/62; H01L 33/00

(52) U.S. Cl. CPC H01L 33/64; H01L 33/0075; H01L 33/50; H01L 33/62
USPC 257/94; 438/27

(57) ABSTRACT

A semiconductor light emitting device package is provided having a light transmissive substrate, and a light emitting structure including a first conductivity-type semiconductor layer, an active layer, and a second conductivity-type semiconductor layer sequentially laminated on the light transmissive substrate. The light emitting structure comprises a first surface and a second opposing surface facing the light transmissive substrate. The semiconductor light emitting device package comprises a via penetrating the second conductivity-type semiconductor layer and the active layer, and exposing the first conductivity-type semiconductor layer. A first electrode has a first portion disposed on the first surface, and a second portion extending into the via and contacting the first conductivity-type semiconductor layer. An insulating layer is disposed between the first electrode, and each of the second conductivity type semiconductor layer, the active layer, and the first surface. A second electrode is disposed on the first surface.

### CROSS-REFERENCE TO RELATED APPLICATION

This application claims the priority of Korean Patent Application No. 10-2013-0054234 filed on May 14, 2013, with the Korean Intellectual Property Office, the disclosure of which is incorporated herein by reference.

### TECHNICAL FIELD

The present disclosure relates to a method of manufacturing a semiconductor light emitting device package.

### BACKGROUND

A light emitting diode (LED) is widely used as a light source due to various advantages thereof, such as low power consumption, a high level of luminance, and the like. In particular, recently, a light emitting device has been employed as a backlight unit in a lighting device and a large liquid crystal display (LCD) device. A light emitting device is provided in the form of a package that can be easily installed in various devices such as lighting devices, or the like. As the use of LEDs has extended into various fields, the size of light emitting device packages should be reduced to allow for a sufficient degree of freedom in the design of lighting devices for specific purposes. In addition, superior heat dissipation performance is a significantly weighed package condition in fields in which high output light emitting devices such as a general lighting device and a backlight for a large LCD device are required.

In general, a package using a package substrate having a through silicon via (TSV) formed therein has been widely used. Of late, research into a package allowing for heat dissipation characteristics of a light emitting device to be enhanced, without increasing manufacturing costs by using a simplified manufacturing process, has been actively conducted.

### SUMMARY

An aspect of the present disclosure provides a semiconductor light emitting device package having improved heat dissipation characteristics and reduced manufacturing costs through use of a simplified manufacturing process.

According to an aspect of the present disclosure, a semiconductor light emitting device package is provided having a light transmissive substrate, and a light emitting structure including a first conductivity-type semiconductor layer, an active layer, and a second conductivity-type semiconductor layer sequentially laminated on the light transmissive substrate. The light emitting structure comprises a first surface and a second opposing surface facing the light transmissive substrate. The semiconductor light emitting device package comprises a via penetrating the second conductivity-type semiconductor layer and the active layer, the via exposing the first conductivity-type semiconductor layer. A first electrode has a first portion disposed on the first surface, and a second portion extending into the via and contacting the first conductivity-type semiconductor layer. An insulating layer is disposed between the first electrode, and each of the second conductivity type semiconductor layer, the active layer, and the first surface; and a second electrode disposed on the first surface.

Certain embodiments of the semiconductor light emitting device package may further comprise a support substrate, wherein the support substrate, first electrode, and second electrode form a substantially planar surface.

In certain embodiments of the semiconductor light emitting device package, the first electrode may be substantially T-shaped.

In certain embodiments of the semiconductor light emitting device package, the insulating layer is bounded by the first electrode.

In certain embodiments, the semiconductor light emitting device package may further comprise a wavelength conversion layer between the light transmissive substrate and the first conductivity-type semiconductor layer.

In certain embodiments, the semiconductor light emitting device package may further comprise an adhesive layer between the wavelength conversion layer and the first conductivity-type semiconductor layer, and the wavelength conversion layer may comprise a phosphor.

In certain embodiments, the semiconductor light emitting device package may further comprise a plurality of first electrodes and second electrodes disposed on the first surface.

The semiconductor light emitting device package may further comprise a lens disposed on the light transmissive substrate, and the lens may be hemispherical-shaped. In certain embodiments, the lens may be a Fresnel lens.

In certain embodiments of the semiconductor light emitting device package, the light emitting structure may comprise a plurality of nano-structures comprising a plurality of first conductivity-type semiconductor rods disposed on the first conductivity-type layer, the active layer disposed on the first conductivity-type semiconductor rods, and the second conductivity-type semiconductor layer disposed on the active layer. The semiconductor light emitting device package may further comprise a filler material between the nano-structures, and may further comprise ohmic contact material on the second conductivity-type semiconductor layer.

In certain embodiments of the semiconductor light emitting device package, the first and second electrodes may cover about 1% to about 5% of a total surface area of the first surface.

In certain embodiments of the semiconductor light emitting device package, a surface of the light transmissive substrate opposite the surface of the light transmissive substrate facing the first conductivity-type semiconductor layer comprises a plurality of alternating protrusions and depressions.

In certain embodiments of the semiconductor light emitting device package, the light transmissive layer comprises at least one of glass, quartz, transparent resin, SiO₂, SiNₓ, Al₂O₃, HfO, TiO₂, and ZrO.

In certain embodiments of the semiconductor light emitting device package, the first conductivity-type and second conductivity-type semiconductor layers may comprise a nitride semiconductor.

In certain embodiments of the semiconductor light emitting device package, the first and second electrodes may comprise one or more of Ag, Al, Ni, Cr, Cu, Au, Pd, Pt, Sn, W, Rh, Ir, Ru, Mg, Zn, Ti, or an alloy thereof.

According to another aspect of the present disclosure, a method of manufacturing a semiconductor light emitting device package is provided. The method comprises sequentially laminating a first conductivity-type semiconductor layer, an active layer, and a second conductivity-type semiconductor layer to form a light emitting structure on a growth substrate, wherein the light emitting structure has a first and an opposing second surface facing the growth substrate. A first electrode is formed in contact with the first conductivity-type semiconductor layer. A second electrode is formed in contact with the second conductivity-type semiconductor layer. A support substrate is disposed on the second conductivity-type semiconductor layer, the first electrode, and the second electrode. At least a portion of the growth substrate is removed. A light transmissive substrate is disposed on the first conductivity-type semiconductor layer. At least a portion of the support substrate is removed to expose the first and second electrodes.

In certain embodiments of the method, during the removing at least a portion of the growth substrate, the entire growth substrate may be removed.

In certain embodiments of the method, during the removing at least a portion of the support substrate, the entire support substrate may be removed.

In certain embodiments of the method, a substantially planar surface may be formed as a result of the removing at least a portion of the support substrate, and the planar surface may comprise a portion of the support substrate remaining after the removing at least a portion of the support substrate, and the first and second electrodes.

In certain embodiments of the method, the support substrate may be removed by a laser lift-off process, chemical-mechanical polishing, wet-etching, or dry etching.

In certain embodiments of the method, the first electrode may be formed by forming a via in the second conductivity-type semiconductor layer and the active layer exposing a surface of the first conductivity-type semiconductor layer, forming an insulating layer on the via sidewall and on the first surface of the light emitting structure, and filling the via with a conductive material. The via may be formed by etching the second conductivity-type semiconductor layer and the active layer, the first electrode may be substantially T-shaped, and the insulating layer may be bounded by the first electrode.

In certain embodiments of the method, the method may further comprise disposing a wavelength conversion layer on the light transmissive substrate before disposing the light transmissive substrate on the first conductivity-type semiconductor layer.

In certain embodiments, the method may further comprise disposing an adhesive layer on the light transmissive substrate before disposing the light transmissive substrate on the first conductivity-type semiconductor layer. The method may further comprise disposing a wavelength conversion layer between the light transmissive substrate and the adhesive layer.

In certain embodiments, the method may further comprise forming a plurality of first electrodes and second electrodes on the first surface.

In certain embodiments, the method may further comprise disposing a lens on the light transmissive substrate. The lens may be formed by depositing a resin on the light transmissive substrate, and shaping the resin to form the lens using a stamp.

In certain embodiments of the method, the light emitting structure comprises a plurality of nano-structures formed by forming a plurality of first conductivity-type semiconductor rods on the first conductivity-type layer, disposing the active layer on the first conductivity-type semiconductor rods, and disposing a second conductivity-type semiconductor layer on the active layer. The method may further comprise disposing a filler material between the nano-structures, and may further comprise disposing an ohmic contact material on the second conductivity-type semiconductor layer.

According to another aspect of the present disclosure, a semiconductor light emitting device package is provided having a light transmissive substrate, and a light emitting structure including a first conductivity-type semiconductor layer, an active layer, and a second conductivity-type semiconductor layer sequentially laminated on the light transmissive substrate. The light emitting structure comprises a first surface and a second opposing surface facing the light transmissive substrate. The semiconductor light emitting device package comprises a via penetrating the second conductivity-type semiconductor layer and the active layer, the via exposing the first conductivity-type semiconductor layer. A first electrode extends into the via and contacting the first conductivity-type semiconductor layer. An insulating layer is formed only between the first electrode, and each of the second conductivity type semiconductor layer and the active layer. A second electrode is disposed on the first surface.

In certain embodiments, the semiconductor light emitting device package may further comprise a support substrate, wherein the support substrate, first electrode, and second electrode form a substantially planar surface.

In certain embodiments of the semiconductor light emitting device package, the insulating layer is bounded by the first electrode.

In certain embodiments, the semiconductor light emitting device package may further comprise a wavelength conversion layer between the light transmissive substrate and the first conductivity-type semiconductor layer.

In certain embodiments, the semiconductor light emitting device package may further comprise an adhesive layer between the wavelength conversion layer and the first conductivity-type semiconductor layer. The wavelength conversion layer may comprise a phosphor.

In certain embodiments, the semiconductor light emitting device package further comprises a plurality of first electrodes and second electrodes disposed on the first surface.

In certain embodiments of the semiconductor light emitting device package, a surface of the light transmissive substrate opposite the surface of the light transmissive substrate facing the first conductivity-type semiconductor layer may comprise a plurality of alternating protrusions and depressions.

In certain embodiments, the semiconductor light emitting device package may further comprise a lens disposed on the light transmissive substrate. The lens may be hemispherical-shaped or the lens may be a Fresnel lens.

In certain embodiments of the semiconductor light emitting device package, the light emitting structure may comprise a plurality of nano-structures comprising a plurality of first conductivity-type semiconductor rods disposed on the first conductivity-type layer, the active layer disposed on the first conductivity-type semiconductor rods, and the second conductivity-type semiconductor layer disposed on the active layer. The semiconductor light emitting device package may further comprise a filler material between the nano-structures, and may further comprise an ohmic contact material on the second conductivity-type semiconductor layer.

In certain embodiments of the semiconductor light emitting device package, the first and second electrodes may cover about 1% to about 5% of a total surface area of the first surface, and the light transmissive layer may comprise at least one of glass, quartz, transparent resin, SiO₂, SiNₓ, Al₂O₃, HfO, TiO₂, and ZrO.

In certain embodiments of the semiconductor light emitting device package, the first conductivity-type and second conductivity-type semiconductor layers may comprise a nitride semiconductor.

In certain embodiments of the semiconductor light emitting device package, the first and second electrodes may comprise one or more of Ag, Al, Ni, Cr, Cu, Au, Pd, Pt, Sn, W, Rh, Ir, Ru, Mg, Zn, Ti, or an alloy thereof.

### BRIEF DESCRIPTION OF THE DRAWINGS

The above and other aspects, features and other advantages of the present inventive concept will be more clearly understood from the following detailed description taken in conjunction with the accompanying drawings, in which:

FIG. 1 is a schematic cross-sectional view of a semiconductor light emitting device package according to an embodiment of the present inventive concept;

FIGS. 2A through 2I are views schematically illustrating a method of manufacturing a semiconductor light emitting device package according to an embodiment of the present inventive concept;

FIG. 3 is a schematic cross-sectional view of a semiconductor light emitting device package according to an embodiment of the present inventive concept;

FIG. 4 is a schematic cross-sectional view of a semiconductor light emitting device package according to an embodiment of the present inventive concept;

FIG. 5 is a schematic cross-sectional view of a semiconductor light emitting device package according to an embodiment of the present inventive concept;

FIG. 6 is a schematic cross-sectional view of a semiconductor light emitting device package according to an embodiment of the present inventive concept;

FIG. 7 is a schematic cross-sectional view of a semiconductor light emitting device package according to an embodiment of the present inventive concept;

FIG. 8 is a schematic cross-sectional view of a semiconductor light emitting device package according to an embodiment of the present inventive concept;

FIG. 9 is a schematic cross-sectional view of a semiconductor light emitting device package according to an embodiment of the present inventive concept;

FIGS. 10 and 11 illustrate examples of applying a semiconductor light emitting device package according to an embodiment of the present inventive concept to backlight units;

FIG. 12 illustrates an example of applying a semiconductor light emitting device package according to an embodiment of the present inventive concept to a lighting device; and

FIG. 13 illustrates an example of applying a semiconductor light emitting device package according to an embodiment of the present inventive concept to a headlamp.

### DETAILED DESCRIPTION OF THE EMBODIMENTS

Embodiments of the present inventive concept will now be described in detail with reference to the accompanying drawings.

The inventive concept may, however, be exemplified in many different forms and should not be construed as being limited to the specific embodiments set forth herein. Rather, these embodiments are provided so that this disclosure will be thorough and complete, and will fully convey the scope of the inventive concept to those skilled in the art.

In the drawings, the shapes and dimensions of elements may be exaggerated for clarity, and the same or like reference numerals will be used throughout to designate the same or like elements.

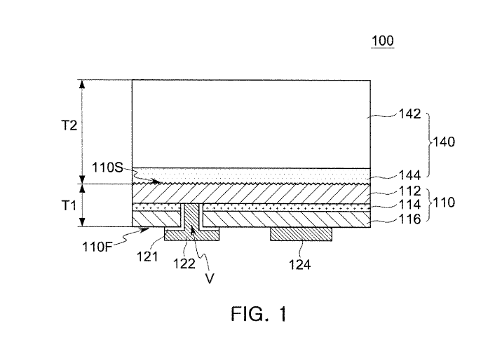

FIG. 1 is a schematic cross-sectional view of a semiconductor light emitting device package according to an embodiment of the present inventive concept.

With reference to FIG. 1, a semiconductor light emitting device package 100 according to an embodiment of the inventive concept may include a light emitting structure 110 having a first surface 110F and a second surface 110S, and first and second electrodes 122 and 124, and may further include a light transmissive substrate 140 disposed on the second surface 110S of the light emitting structure 110. The semiconductor light emitting device package 100 according to the present embodiment may be a chip scale package (CSP), and alternatively, the semiconductor light emitting device package may be a wafer level package (WLP).

The light emitting structure 110 may include a first conductivity-type semiconductor layer 112, an active layer 114 and a second conductivity-type semiconductor layer 116. The light transmissive substrate 140 may include a substrate body 142 and a wavelength conversion layer 144.

In the present disclosure, terms such as ‘upper portion’, ‘upper surface’, ‘lower portion’, ‘lower surface’, ‘lateral surface’, and the like, are determined based on the drawings, and in actuality, the terms may be changed according to a direction in which a device or a package is disposed.

The first and second conductivity-type semiconductor layers 112 and 116 may be n-type and p-type semiconductor layers, respectively, but the invention is not limited thereto and, conversely, the first and second conductivity-type semiconductor layers 112 and 116 may be p-type and n-type semiconductor layers, respectively. The first and second conductivity-type semiconductor layers 112 and 116 may be made of a nitride semiconductor, e.g., a material having a composition of AlₓIn_{y}Ga_{1-x-y}N (0≦x≦1, 0≦y≦1, 0≦x+y≦1). Each of the semiconductor layers 112 and 116 may be configured as a single layer, or may include a plurality of layers having different characteristics such as different doping concentrations, compositions, and the like. The first and second conductivity-type semiconductor layers 112 and 116 may be made of an AlInGaP or AlInGaAs semiconductor, besides the nitride semiconductor.

As shown in FIG. 1, a surface of the first conductivity-type semiconductor layer 112, i.e., the second surface 110S of the light emitting structure 110 may be formed as a concave-convex surface to enhance light extraction efficiency. For example, depressions and protrusions (concave and convex portions) may be obtained by wet-etching the first conductivity-type semiconductor layer 112 or dry-etching the same by using plasma after removing a semiconductor layer growth substrate from the light emitting structure 110.

The active layer 114, disposed between the first and second conductivity-type semiconductor layers 112 and 116, emits light having a certain level of energy according to the recombination of electrons and holes and may have a multi-quantum well (MQW) structure in which quantum well layers and quantum barrier layers are alternately laminated. For example, in the case of the nitride semiconductor, a GaN/InGaN structure may be used. Alternatively, a single quantum well (SQW) structure may also be used.

The first and second electrodes 122 and 124 may be positioned on the first surface 110F of the light emitting structure 110. The first and second electrodes 122 and 124 may be bonded to an external device such as a module substrate on which the semiconductor light emitting device package 100 is mounted, thereby electrically connecting the light emitting structure 110 to the external device.

The first and second electrodes 122 and 124 may be made of a conductive material. For example, the first and second electrodes 122 and 124 may be made of one or more of silver (Ag), aluminum (Al), nickel (Ni), chromium (Cr), copper (Cu), gold (Au), palladium (Pd), platinum (Pt), tin (Sn), tungsten (W), rhodium (Rh), iridium (Ir), ruthenium (Ru), magnesium (Mg), zinc (Zn), titanium (Ti), or an alloy material including one or more of these elements. The first electrode 122 may be substantially T-shaped.

In the present embodiment, the first electrode 122 may include at least one via (v) electrically connected to the first conductivity-type semiconductor layer 112 by passing through the second conductivity-type semiconductor layer 116 and the active layer 114. The via v may penetrate the second conductivity-type semiconductor layer 116 and the active layer 114, thereby exposing the first conductivity-type semiconductor layer. An insulating layer 121 may be formed to surround the via v in order to electrically insulate the first electrode 122 from the second conductivity-type semiconductor layer 116 and the active layer 114. The insulating layer 121 may also insulate the first electrode from the first surface 110F of the light emitting structure 110. A plurality of vias may be formed and may be arranged in a plurality of rows and columns.

According to embodiments, the first electrode 122 may not include the via v, but may be disposed on a portion of the first conductivity-type semiconductor layer 112 exposed by partially etching the light emitting structure 110.

The substrate body 142 of the light transmissive substrate 140 may be made of a transparent material. For example, the substrate body 142 may be made of a light-transmissive insulating material, and may be made of at least one of glass, quartz, transparent resin, SiO₂, SiNₓ, Al₂O₃, HfO, TiO₂ and ZrO.

The wavelength conversion layer 144 may be formed on a surface of the substrate body 142 to be in contact with the second surface 110S of the light emitting structure 110, and may include phosphors excited by light emitted from the light emitting structure 110 to emit light beams having different wavelengths. Light emitted from the phosphors and light emitted from the light emitting structure 110 may be combined to output desired light such as white light, or the like. According to embodiments, the wavelength conversion layer 144 may not be separately provided, but the substrate body 142 may include phosphors dispersed therein.

The light emitting structure 110 may have a first thickness T1, and the light transmissive substrate 140 may have a second thickness T2 greater than the first thickness T1. For example, the second thickness T2 may range from 10 μm to 500 μm. If the light transmissive substrate 140 is relatively thin, the stability of the semiconductor light emitting device package 100 may be degraded, and the semiconductor light emitting device including the light emitting structure 110 and the first and second electrodes 122 and 124 may be damaged during a manufacturing process thereof. Therefore, the light transmissive substrate 140 may have a thickness greater than that of the light emitting structure 110 and appropriate for the miniaturization of the semiconductor light emitting device package 100.

In the case of the semiconductor light emitting device package 100 according to the present embodiment, the first and second electrodes 122 and 124 may serve as electrode pads to be directly mounted on the external device, whereby the manufacturing process may be simplified and manufacturing costs may be reduced. In addition, there is no additional package substrate between the light emitting structure 110 and the external device on which the semiconductor light emitting device package 100 is to be mounted, and thus, heat generated in the light emitting structure 110 may be effectively dissipated.

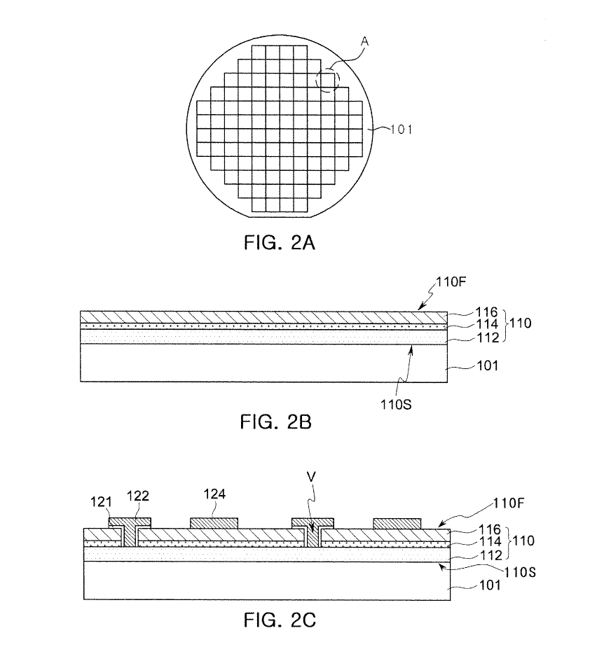

FIGS. 2A through 2I are views schematically illustrating a method of manufacturing a semiconductor light emitting device package according to an embodiment of the present inventive concept.

With reference to FIG. 2A, a substrate 101 including a plurality of device regions A constituting a plurality of semiconductor light emitting devices may be prepared.

For example, the substrate 101 may be a semiconductor wafer, and a light emitting structure for forming the plurality of semiconductor light emitting devices may be simultaneously manufactured thereon. For example, a single device region A may have a square shape, a rectangular shape, a triangular shape, or any other polygonal shape having a length ranging from 300 μm to 10000 μm.

The substrate 101 may be provided as a semiconductor growth substrate. The substrate 101 may be made of an insulating, conductive or semiconductor material, such as sapphire, SiC, Si, MgAl₂O₄, MgO, LiAlO₂, LiGaO₂ or GaN. Sapphire commonly used as a nitride semiconductor growth substrate is a crystal having electrical insulating properties and Hexa-Rhombo R3c symmetry, and has a lattice constant of 13.001 Å along a C-axis and a lattice constant of 4.758 Å along an A-axis. Orientation planes of the sapphire include a C (0001) plane, an A (1120) plane, an R (1102) plane, and the like. Particularly, the C plane is mainly used as a substrate for nitride growth because it relatively facilitates the growth of a nitride film and is stable at high temperatures. Meanwhile, a silicon (Si) substrate may also be appropriately used as the substrate 101, and mass-production can be enhanced by using a silicon (Si) substrate which may have a large diameter and may be relatively low in price.

With reference to FIG. 2B, the first conductivity-type semiconductor layer 112, the active layer 114 and the second conductivity-type semiconductor layer 116 may be sequentially grown on the substrate 101, thereby forming the light emitting structure 110. In FIG. 2B and the following drawings, the manufacturing method will be described in a manner of illustrating portions of two adjacent light emitting device packages, but the following processes may be performed on a wafer level.

The light emitting structure 110 may be grown by metal organic chemical vapor deposition (MOCVD), hydride vapor phase epitaxy (HVPE), molecular beam epitaxy (MBE), or the like.

In order to help in an understanding of the manufacturing method, an upper surface of the light emitting structure 110, which is a surface of the second conductivity-type semiconductor layer 116, is referred to as the first surface 110F, and a lower surface thereof in contact with the substrate 101 is referred to as the second surface 110S.

With reference to FIG. 2C, in order to form the via v constituting the first electrode 122, a via hole may be formed to pass through the second conductivity-type semiconductor layer 116 and the active layer 114 by an etching process using a mask, and then the insulating layer 121 may be formed.

The number of vias v is not limited to that illustrated in FIG. 2C, and the plurality of vias v may be formed in a single device region A of FIG. 2A. The number of vias v and an overall contact area thereof with the first conductivity-type semiconductor layer 112 may be adjusted such that the area occupied by the plurality of vias v on a plane ranges from 1% to 5% of an area of the light emitting structure 110 formed on a single device region A.

The first and second electrodes 122 and 124 may be formed by depositing a conductive ohmic-material on the first surface 110F of the light emitting structure 110. For example, the first and second electrodes 122 and 124 may employ various materials or lamination structures in order to enhance ohmic characteristics or reflective characteristics.

With reference to FIG. 2D, a support substrate 130 may be bonded to the first surface 110F of the light emitting structure 110.

A material of the support substrate 130 is not particularly limited. The support substrate 130 may be formed of an insulating material or a conductive material including any one of Au, Ni, Al, Cu, W, Si, Se, and GaAs. For example, the support substrate 130 may be an Si substrate doped with Al.

The bonding process may be performed using a separate adhesive, or may be performed through oxide-oxide bonding or oxide-silicon (Si) bonding.

With reference to FIG. 2E, the substrate 101 may be removed.

In order to remove the substrate 101, a wet-etching process, a dry-etching process or a laser lift-off process may be used. According to embodiments, mechanical polishing may also be used.

Since the support substrate 130 is bonded to the first surface 110F of the light emitting structure 110, even after the substrate 101 is removed from the second surface 110S of the light emitting structure 110, the light emitting structure 110 having a relatively small thickness may be easily handled.

With reference to FIG. 2F, the light transmissive substrate 140 including the substrate body 142 and the wavelength conversion layer 144 may be prepared.

The wavelength conversion layer 144 may be formed on the substrate body 142 through a relatively simple process, for example, spray coating or spin coating. Alternatively, a sheet such as a phosphor film or a ceramic phosphor film may be attached to the substrate body 142.

Next, an adhesive layer 150 may be formed on the light transmissive substrate 140.

With reference to FIG. 2G the light emitting structure 110 disposed on the support substrate 130 described above with reference to FIG. 2D and the light transmissive substrate 140 described above with reference to 2F may be bonded to one another. Before the bonding process, depressions and protrusions may be formed on the first conductivity-type semiconductor layer 112 of the light emitting structure 110.

The first conductivity-type semiconductor layer 112 of the light emitting structure 110 and the wavelength conversion layer 144 of the light transmissive substrate 140 may be bonded to one another through the adhesive layer 150 of FIG. 2F. Since FIG. 2G shows the structure after the bonding process, the adhesive layer 150 is not illustrated in FIG. 2G.

With reference to FIG. 2H, the support substrate 130 may be removed.

In a case in which the support substrate 130 is made of a transparent material, the support substrate 130 may be removed using a laser lift-off (LLO) process. In a case in which the support substrate 130 is made of a non-transparent material, the support substrate 130 may be removed by a mechanical polishing process or a wet-etching or dry-etching process.

Since the light transmissive substrate 140 is bonded to the second surface 110S of the light emitting structure 110, even after the support substrate 130 is removed, damage to the light emitting structure 110 may be prevented during post-processing.

With reference to FIG. 2I, the light emitting structure 110 may be divided into semiconductor light emitting device packages.

Finally, the semiconductor light emitting device package 100 of FIG. 1 may be manufactured. According to the present embodiment, the light transmissive substrate 140 is bonded to the second surface 110S of the light emitting structure 110, whereby the semiconductor light emitting device package 100 may be formed without an additional package substrate disposed below the first and second electrodes 122 and 124. Therefore, a process of forming an electrode pattern on the package substrate, forming vias therein or the like may be omitted, whereby the manufacturing process may be simplified and the manufacturing costs may be reduced. In addition, the bonding of the light transmissive substrate 140 may facilitate the forming of the wavelength conversion layer 144.

In addition, since there is no additional package substrate below the light emitting structure 110, the dissipation of heat from the semiconductor light emitting device package 100 may be improved.

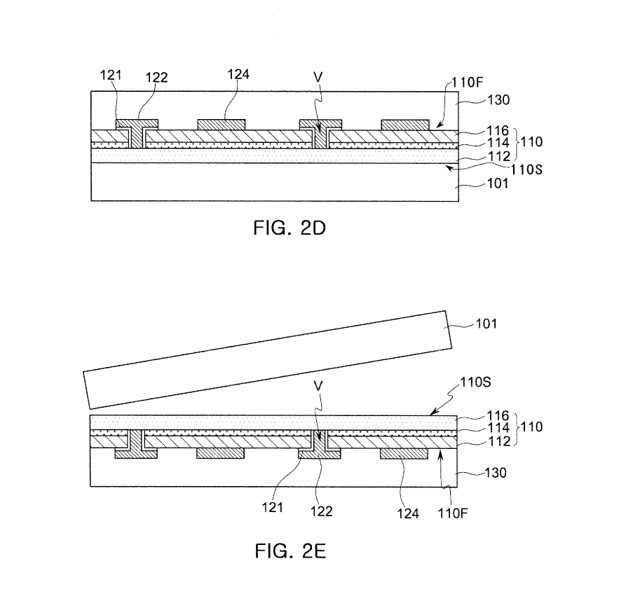

FIG. 3 is a schematic cross-sectional view of a semiconductor light emitting device package according to an embodiment of the present inventive concept.

With reference to FIG. 3, a semiconductor light emitting device package 100a according to an embodiment of the inventive concept may include a light emitting structure 110a and the first and second electrodes 122 and 124, and may further include a light transmissive substrate 140a disposed on the light emitting structure 110a.

The light emitting structure 110a may include a first conductivity-type semiconductor layer 112a, the active layer 114 and the second conductivity-type semiconductor layer 116. The light transmissive substrate 140a may include a substrate body 142a and the wavelength conversion layer 144.

In the present embodiment, the first conductivity-type semiconductor layer 112a may have no depressions and protrusions on an upper surface thereof, unlike the semiconductor light emitting device package 100 of FIG. 1. Instead, the depressions and protrusions may be formed on an upper surface of the substrate body 142a of the light transmissive substrate 140a from which light is emitted. According to embodiments, the depressions and protrusions may also be formed on the first conductivity-type semiconductor layer 112a.

Due to the depressions and protrusions, light emitted from the active layer 114 may be directed upwardly by being transmitted or multiply reflected when incident into surrounding air. Therefore, the light extraction efficiency of the semiconductor light emitting device package 100a may be improved. According to embodiments, the upper surface of the substrate body 142a may have a prism lattice structure due to the depressions and protrusions.

The depressions and protrusions may be obtained by etching the upper surface of the substrate body 142a, before dividing the light emitting structure 110 into the individual semiconductor light emitting device packages in the manufacturing process described above with reference to FIG. 2I. Alternatively, according to embodiments, the substrate body 142a including the depressions and protrusions formed thereon may be prepared by curing a resin using a stamp provided with depressions and protrusions in the preparing of the light transmissive substrate 140 described above with reference to FIG. 2F.

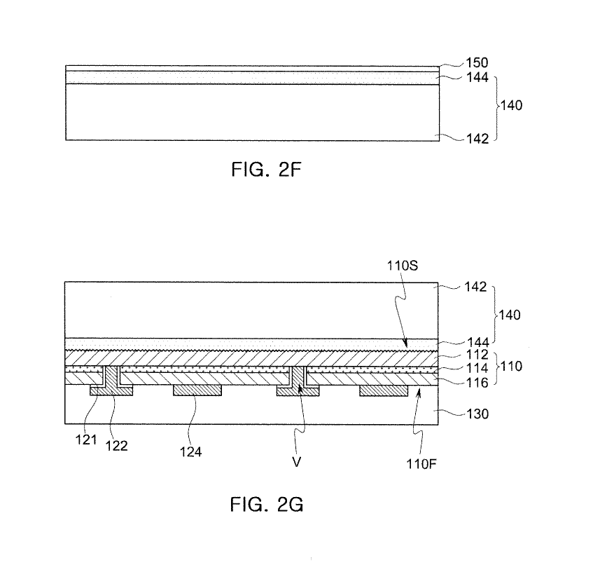

FIG. 4 is a schematic cross-sectional view of a semiconductor light emitting device package according to an embodiment of the present inventive concept.

With reference to FIG. 4, a semiconductor light emitting device package 100b according to an embodiment of the inventive concept may include the light emitting structure 110 and the first and second electrodes 122 and 124, and may further include a light transmissive substrate 140b disposed on the light emitting structure 110. The light transmissive substrate 140b may include a substrate body 142b and the wavelength conversion layer 144.

In the present embodiment, an upper surface of the substrate body 142b from which light is emitted may have a hemispherical shape. Therefore, the substrate body 142b may serve as a lens, and according to embodiments, the substrate body 142b may have a Fresnel lens shape.

The substrate body 142b may be formed by etching an upper portion of the substrate body 142b, before dividing the light emitting structure 110 into the individual semiconductor light emitting device packages in the manufacturing process described above with reference to FIG. 2I. Alternatively, according to embodiments, the substrate body 142b having the hemispherical shape may be prepared by curing a resin using a stamp provided with depressions and protrusions in the preparing of the light transmissive substrate 140 described above with reference to FIG. 2F.

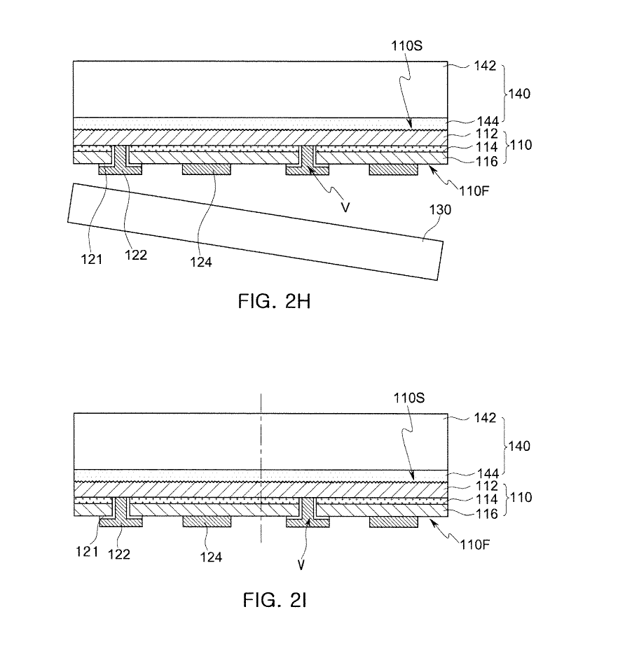

FIG. 5 is a schematic cross-sectional view of a semiconductor light emitting device package according to an embodiment of the present inventive concept.

With reference to FIG. 5, a semiconductor light emitting device package 100c according to an embodiment of the inventive concept may include the light emitting structure 110 and the first and second electrodes 122 and 124, and may further include the light transmissive substrate 140 and a lens unit 160 disposed above the light emitting structure 110. The substrate body 142 of the light transmissive substrate 140 may have a third thickness T3 less than the second thickness T2 of the embodiment of FIG. 1.

The lens unit 160 may be made of a material having excellent light transmission and heat resistance properties, such as, for example, silicon, epoxy, glass, plastic, or the like. The lens unit 160, having a convex or concave lens structure, may be able to regulate an angle of beam spread of light emitted through an upper surface thereof. The lens unit 160 may be selectively made of a resin having a high level of transparency allowing light generated by the light emitting structure 110 to pass therethrough with a minimum amount of loss. For example, an elastic resin, silicone, an epoxy resin, or plastic may be used as a material of the lens unit 160.

As shown in FIG. 5, the lens unit 160 may have a structure having a dome-like shape with a convex upper surface, but the shape of the lens unit is not limited thereto. For example, in order to enhance light diffusion in a lighting device or a backlight unit, the lens unit 160 may include colloid particles positioned on a surface thereof, and may have a flat upper surface. Alternatively, the lens unit 160 may have an aspherical surface and/or an asymmetrical shape or may have depressions and protrusions on an upper surface thereof. Also, in order to enhance linear properties of light (or linear propagation of light) from a camera flash, or the like, the lens unit 160 may include a light condenser having a Fresnel shape and an upper surface thereof may have depressions and protrusions.

The lens unit 160 may be formed by spray coating the light transmissive substrate 140, before dividing the light emitting structure 110 into the individual semiconductor light emitting device packages in the manufacturing process described above with reference to FIG. 2I. Alternatively, the lens unit 160 may be formed to have a predetermined shape on the light transmissive substrate 140 and be cured.

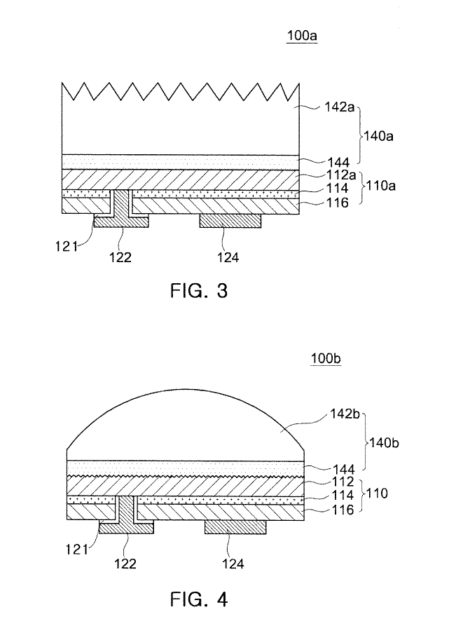

FIG. 6 is a schematic cross-sectional view of a semiconductor light emitting device package according to an embodiment of the present inventive concept.

With reference to FIG. 6, a semiconductor light emitting device package 100d according to an embodiment of the inventive concept may include the light emitting structure 110 and the first and second electrodes 122 and 124, and may further include the light transmissive substrate 140 disposed on the light emitting structure 110 and a support substrate 130a disposed below the light emitting structure 110.

The support substrate 130a and the first and second electrodes 122 and 124 may have the same lower surface, and the support substrate 130a may be disposed on lateral surfaces of the first and second electrodes 122 and 124. The support substrate 130a may be obtained by partially removing the support substrate 130 of FIG. 2H, not entirely removing the same, in the removing of the support substrate 130 described above with reference to FIG. 2H. In this case, the support substrate 130a may be made of an insulating material.

The support substrate 130a may protect the second conductivity-type semiconductor layer 116 and the first and second electrodes 122 and 124, and may facilitate the handling of the semiconductor light emitting device package 100d.

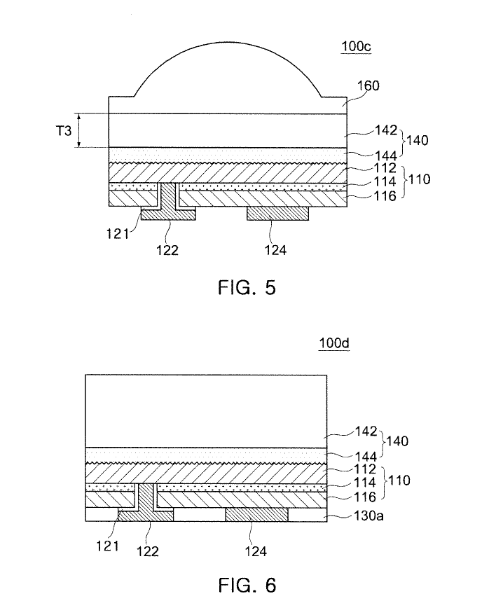

FIG. 7 is a schematic cross-sectional view of a semiconductor light emitting device package according to an embodiment of the present inventive concept.

With reference to FIG. 7, a semiconductor light emitting device package 100e according to an embodiment of the inventive concept may include the light emitting structure 110 and the first and second electrodes 122 and 124, and may further include the light transmissive substrate 140 disposed on the light emitting structure 110, the support substrate 130a disposed below the light emitting structure 110 and first and second bumps 172 and 174.

The first and second bumps 172 and 174 may be provided to make connections with an external device and may be connected to the first and second electrodes 122 and 124, respectively. The first and second bumps 172 and 174 may protrude from the first and second electrodes 122 and 124 to be exposed outwardly. The shape of the first and second bumps 172 and 174 is not limited to that illustrated in FIG. 7, and for example, the first and second bumps 172 and 174 may have a pillar shape such as a quadrangular pillar shape or a cylindrical shape.

For example, the first and second bumps 172 and 174 may be solder bumps. According to embodiments, the first and second bumps 172 and 174 may include at least one of copper (Cu), aluminum (Al), silver (Ag), tin (Sn) and gold (Au).

The first and second bumps 172 and 174 may be formed on the exposed first and second electrodes 122 and 124 by various methods such as electroplating, solder printing or ball dropping, after forming the support substrate 130a by partially removing the support substrate 130 in the removing of the support substrate 130 described above with reference to FIG. 2H.

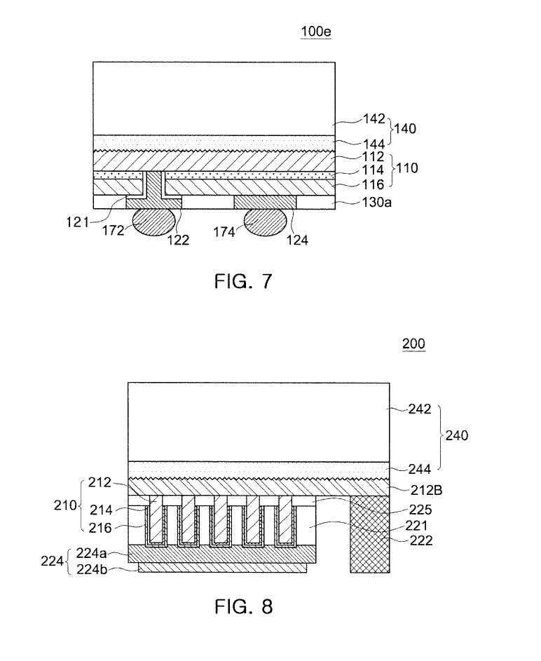

FIG. 8 is a schematic cross-sectional view of a semiconductor light emitting device package according to an embodiment of the present inventive concept.

With reference to FIG. 8, a semiconductor light emitting device package 200 according to an embodiment of the inventive concept may include a light emitting nano-structure 210 and first and second electrodes 222 and 224, and may further include a light transmissive substrate 240 disposed above the light emitting nano-structure 210.

The semiconductor light emitting device package 200 may further include a first conductivity-type semiconductor base layer 212B, an insulating layer 225 and a filler 221. The light emitting nano-structure 210 may include a first conductivity-type semiconductor core 212 grown on the first conductivity-type semiconductor base layer 212B, an active layer 214 and a second conductivity-type semiconductor layer 216.

The plurality of light emitting nano-structures 210 may be formed on the first conductivity-type semiconductor base layer 212B. The light emitting nano-structure 210 may have a core-shell structure such as a rod structure, but the structure thereof is not limited thereto. The light emitting nano-structure 210 may have a different structure such as a pyramid structure. For example, according to embodiments, the light emitting nano-structure 210 may include a nano-wire, a quantum dot, or a nano-box structure. Besides, the light emitting nano-structure 210 may have a structure having a sloped surface with respect to an upper surface of the first conductivity-type semiconductor base layer 212B, and a cross-section of the light emitting nano-structure 210 parallel to the first conductivity-type semiconductor base layer 212B may have various shapes such as polygonal shapes such as a triangular shape, a quadrangular shape, a pentagonal shape, a hexagonal shape, and an octagonal shape, or a circular shape.

The first conductivity-type semiconductor base layer 212B may provide a growth surface for the light emitting nano-structures 210. The insulating layer 225 may provide an open region for the growth of the light emitting nano-structure 210 and may be made of a dielectric material such as SiO₂ or SiNₓ. A size of the open region may range from 5 nm to 10 um.

The filler 221 may structurally stabilize the light emitting nano-structures 210, and may serve to allow light to be transmitted therethrough or may reflect light. In a case in which the filler 221 includes a light-transmissive material, the filler 221 may be made of a transparent material such as SiO₂, SiNx, an elastic resin, silicone, an epoxy resin, a polymer, or plastic. In a case in which the filler 221 includes a reflective material, the filler 221 may be made of a polymer material such as polyphthalamide (PPA), or the like, including TiO₂, Al₂O₃, or the like, having a high level of light reflectivity, and may be made of a material having high heat resistance and light fastness qualities.

The first and second electrodes 222 and 224 may be disposed on a lower surface of the light emitting nano-structures 210. The first electrode 222 may be positioned on an exposed upper surface of the first conductivity-type semiconductor base layer 212B, and the second electrode 224 may include an ohmic contact layer 224a formed below the light emitting nano-structures 210 and the filler 221 and an electrode extending portion 224b. According to embodiments, the ohmic-contact layer 224a and the electrode extending portion 224b may be integrally formed. The ohmic-contact layer 224a may be made of a reflective or light-transmissive material. The reflective material may include silver (Ag), aluminum (Al), or alloys thereof, and the ohmic-contact layer 224a may have a multilayer structure including these elements. Alternatively, a reflective structure using a distributed Bragg reflector (DBR) may also be used.

In the semiconductor light emitting device package 200 according to the present embodiment, the light emitting nano-structures 210 may be formed instead of the forming of the light emitting structure 110 described above with reference to FIG. 2B, and the first and second electrodes 222 and 224 may be formed instead of the forming of the first and second electrodes 122 and 124 described above with reference to FIG. 2C.

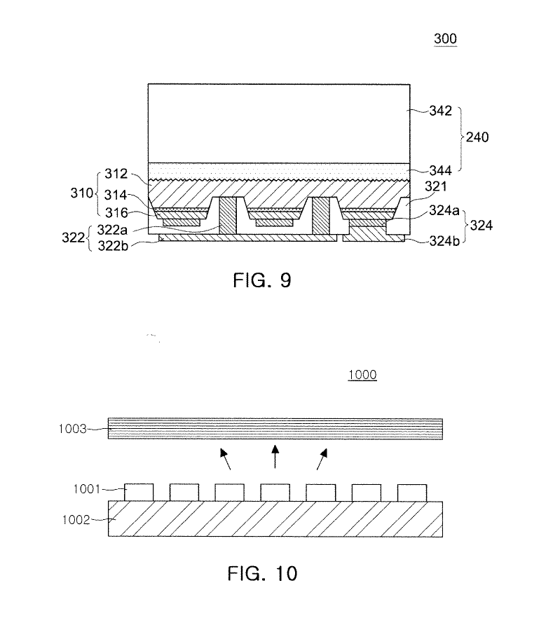

FIG. 9 is a schematic cross-sectional view of a semiconductor light emitting device package according to an embodiment of the present inventive concept.

With reference to FIG. 9, a semiconductor light emitting device package 300 according to an embodiment of the inventive concept may include a light emitting structure 310 and first and second electrodes 322 and 324, and may further include a light transmissive substrate 340 disposed on the light emitting structure 310.

The light emitting structure 310 may include a first conductivity-type semiconductor layer 312, an active layer 314, and a second conductivity-type semiconductor layer 316. The light transmissive substrate 340 may include a substrate body 342 and a wavelength conversion layer 344.

The first electrode 332 may include conductive vias 322a connected to the first conductivity-type semiconductor layer 312 by passing through the second conductivity-type semiconductor layer 316 and the active layer 314 and an electrode extending portion 322b connecting the conductive vias 322a to one another. The conductive vias 322a may be enclosed by an insulating layer 321 to be electrically separated from the active layer 314 and the second conductivity-type semiconductor layer 316. The conductive vias 322a may be positioned in etched regions of the light emitting structure 310, and a degree of inclination of a lateral surface of the light emitting structure 310 may be changed according to embodiments. In order to reduce contact resistance, the conductive vias 322a may be appropriately adjusted in terms of number, shape, pitch, and areas thereof in contact with the first conductivity-type semiconductor layer 312. In addition, the conductive vias 322a may be arranged in rows and columns to thereby improve current flow.

The second electrode 324 may include an ohmic contact layer 324a on the second conductivity-type semiconductor layer 316 and an electrode extending portion 324b.

In the semiconductor light emitting device package 300 according to the present embodiment, the light emitting structures 310 may be formed instead of the forming of the light emitting structure 110 described above with reference to FIG. 2B, and the first and second electrodes 322 and 324 may be formed instead of the forming of the first and second electrodes 122 and 124 described above with reference to FIG. 2C.

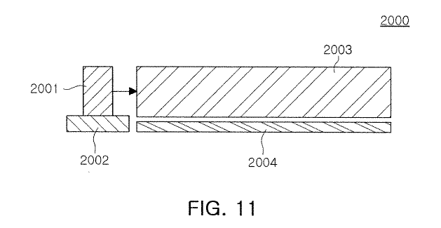

FIGS. 10 and 11 illustrate examples of applying a semiconductor light emitting device package according to an embodiment of the present inventive concept to backlight units.

With reference to FIG. 10, a backlight unit 1000 includes a light source 1001 mounted on a substrate 1002 and at least one optical sheet 1003 disposed thereabove. The light source 1001 may be a semiconductor light emitting device package having the above-described structure of FIGS. 1 and 3 through 9 or a structure similar thereto. For example, the first and second electrodes 122 and 124 of the semiconductor light emitting device package 100 of FIG. 1 may be connected to an electrode pattern of the substrate 1002.

The light source 1001 in the backlight unit 1000 of FIG. 10 emits light toward a liquid crystal display (LCD) device disposed thereabove, whereas a light source 2001 mounted on a substrate 2002 in a backlight unit 2000 of FIG. 11 emits light laterally and the light is incident to a light guide plate 2003 such that the backlight unit 2000 may serve as a surface light source. The light travelling to the light guide plate 2003 may be emitted upwardly and a reflective layer 2004 may be formed below a lower surface of the light guide plate 2003 in order to improve light extraction efficiency.

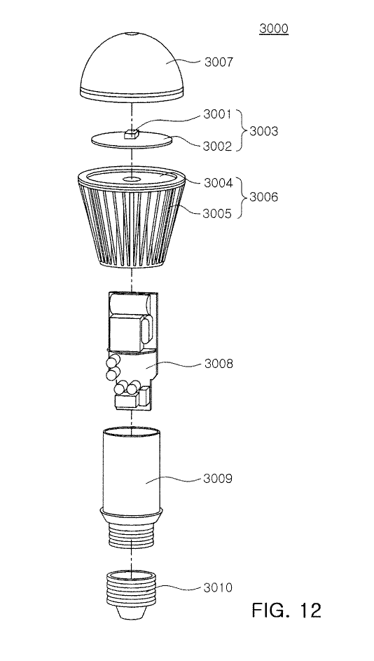

FIG. 12 illustrates an example of applying a semiconductor light emitting device package according to an embodiment of the present inventive concept to a lighting device.

With reference to an exploded perspective view of FIG. 12, a lighting device 3000 is exemplified as a bulb-type lamp, and includes a light emitting module 3003, a driving unit 3008 and an external connector unit 3010. In addition, exterior structures, such as external and internal housings 3006 and 3009, a cover unit 3007, and the like, may be additionally included. The light emitting module 3003 may include a light source 3001 having the above-described structure of the semiconductor light emitting device package of FIGS. 1 and 3 through 9 or a structure similar thereto and a circuit board 3002 having the light source 3001 mounted thereon. For example, the first and second electrodes 122 and 124 of the semiconductor light emitting device package 100 of FIG. 1 may be connected to an electrode pattern of the circuit board 3002. In the present embodiment, a single light source 3001 is mounted on the circuit board 3002; however, if necessary, a plurality of light sources may be mounted thereon.

The external housing 3006 may serve as a heat radiating unit, and may include a heat sink plate 3004 in direct contact with the light emitting module 3003 to thereby improve heat dissipation, and a heat radiating fin 3005 surrounding a lateral surface of the lighting device 3000. In addition, the cover unit 3007 may be disposed above the light emitting module 3003 and have a convex lens shape. The driving unit 3008 may be disposed inside the internal housing 3009 and connected to the external connector unit 3010 such as a socket structure to receive power from an external power source. In addition, the driving unit 3008 may convert the received power into power appropriate for driving the semiconductor light emitting device 3001 of the light emitting module 3003 and supply the converted power thereto. For example, the driving unit 3008 may be provided as an AC-DC converter, a rectifying circuit part, or the like.

In addition, although not shown, the lighting device 3000 may further include a communications module.

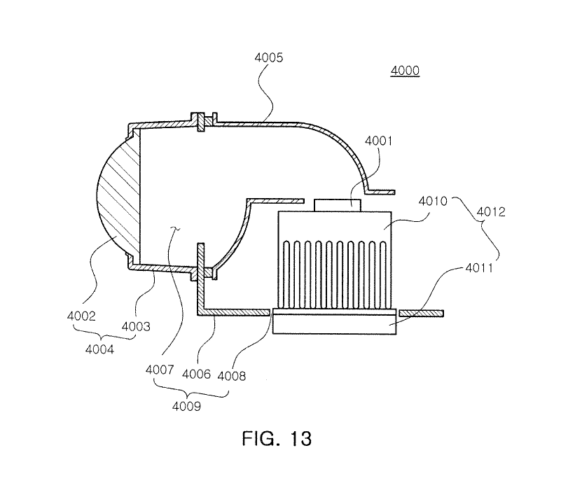

FIG. 13 illustrates an example of applying a semiconductor light emitting device package according to an embodiment of the present inventive concept to a headlamp.

With reference to FIG. 13, a headlamp 4000 used in a vehicle or the like may include a light source 4001, a reflective unit 4005 and a lens cover unit 4004, the lens cover unit 4004 including a hollow guide part 4003 and a lens 4002. The light source 4001 may include at least one semiconductor light emitting device package having the above-described structure of FIGS. 1 and 3 through 9 or a structure similar thereto.

The headlamp 4000 may further include a heat radiating unit 4012 dissipating heat generated in the light source 4001 outwardly. The heat radiating unit 4012 may include a heat sink 4010 and a cooling fan 4011 in order to effectively dissipate heat. In addition, the headlamp 4000 may further include a housing 4009 allowing the heat radiating unit 4012 and the reflective unit 4005 to be fixed thereto and supporting them. One surface of the housing 4009 may be provided with a central hole 408 into which the heat radiating unit 4012 is inserted to be coupled thereto.

The other surface of the housing 4009 bent in a direction perpendicular to one surface of the housing 4009 may be provided with a forwardly open hole 4007 such that light generated in the light source 4001 may be reflected by the reflective unit 4005 disposed above the light source 4001, pass through the forwardly open hole 4007, and be emitted outwardly.

As set forth above, in a method of manufacturing a semiconductor light emitting device package according to embodiments of the inventive concept, heat dissipation characteristics may be improved and manufacturing costs may be reduced, without the use of a package substrate having a through silicon via (TSV) formed therein.

While the present inventive concept has been shown and described in connection with the embodiments, it will be apparent to those skilled in the art that modifications and variations can be made without departing from the spirit and scope of the inventive concept as defined by the appended claims.

What is claimed is:

1. A semiconductor light emitting device package having a light transmissive substrate, and a light emitting structure including a first conductivity-type semiconductor layer, an active layer, and a second conductivity-type semiconductor layer sequentially laminated on the light transmissive substrate, wherein the light emitting structure comprises a first surface and a second opposing surface facing the light transmissive substrate, the semiconductor light emitting device package comprising:
a via penetrating the second conductivity-type semiconductor layer and the active layer, and exposing the first conductivity-type semiconductor layer;
a first electrode having:
a first portion disposed on the first surface, and
a second portion extending into the via and contacting the first conductivity-type semiconductor layer;
an insulating layer disposed between the first electrode, and each of the second conductivity type semiconductor layer, the active layer, and the first surface; and
a second electrode disposed on the first surface.

2. A method of manufacturing a semiconductor light emitting device package, comprising:
sequentially laminating a first conductivity-type semiconductor layer, an active layer, and a second conductivity-type semiconductor layer to form a light emitting structure on a growth substrate, wherein the light emitting structure has a first and an opposing second surface facing the growth substrate;
forming a first electrode in contact with the first conductivity-type semiconductor layer;
forming a second electrode in contact with the second conductivity-type semiconductor layer;
disposing a support substrate on the second conductivity-type semiconductor layer, the first electrode, and the second electrode;
removing at least a portion of the growth substrate;
disposing a light transmissive substrate on the first conductivity-type semiconductor layer; and
removing at least a portion of the support substrate to expose the first and second electrodes.

3. A semiconductor light emitting device package having a light transmissive substrate, and a light emitting structure including a first conductivity-type semiconductor layer, an active layer, and a second conductivity-type semiconductor layer sequentially laminated on the light transmissive substrate, wherein the light emitting structure comprises a first surface and a second opposing surface facing the light transmissive substrate, the semiconductor light emitting device package comprising:
a via penetrating the second conductivity-type semiconductor layer and the active layer, and exposing the first conductivity-type semiconductor layer;
a first electrode extending into the via and contacting the first conductivity-type semiconductor layer;
an insulating layer formed only between the first electrode, and each of the second conductivity type semiconductor layer and the active layer; and
a second electrode disposed on the first surface.

4. The semiconductor light emitting device package of claim 1, further comprising a support substrate, wherein the support substrate, first electrode, and second electrode form a substantially planar surface.

5. The semiconductor light emitting device package of claim 1, wherein the first electrode is substantially T-shaped.

6. The semiconductor light emitting device package of claim 1, wherein the insulating layer is bounded by the first electrode.

7. The semiconductor light emitting device package of claim 1, further comprising a wavelength conversion layer between the light transmissive substrate and the first conductivity-type semiconductor layer.

8. The semiconductor light emitting device package of claim 1, further comprising an adhesive layer between the wavelength conversion layer and the first conductivity-type semiconductor layer.

9. The semiconductor light emitting device package of claim 8, wherein the wavelength conversion layer comprises a phosphor.

10. The semiconductor light emitting device package of claim 1, further comprising a plurality of first electrodes and second electrodes disposed on the first surface.

11. The semiconductor light emitting device package of claim 1, further comprising a lens disposed on the light transmissive substrate.

12. The semiconductor light emitting device package of claim 11, wherein the lens is hemispherical-shaped.

13. The semiconductor light emitting device package of claim 11, wherein the lens is a Fresnel lens.

14. The semiconductor light emitting device package of claim 1, wherein the light emitting structure comprises a plurality of nano-structures comprising:
a plurality of first conductivity-type semiconductor rods disposed on the first conductivity-type layer;
the active layer disposed on the first conductivity-type semiconductor rods; and
the second conductivity-type semiconductor layer disposed on the active layer.

15. The semiconductor light emitting device package of claim 14, further comprising a filler material between the nano-structures.

16. The semiconductor light emitting device package of claim 15, further comprising an ohmic contact material on the second conductivity-type semiconductor layer.

17. The semiconductor light emitting device package of claim 1, wherein the first and second electrodes cover about 1% to about 5% of a total surface area of the first surface.

18. The semiconductor light emitting device package of claim 1, wherein a surface of the light transmissive substrate opposite the surface of the light transmissive substrate facing the first conductivity-type semiconductor layer comprises a plurality of alternating protrusions and depressions.

19. The semiconductor light emitting device package of claim 1, wherein the light transmissive layer comprises at least one of glass, quartz, transparent resin, SiO₂, SiNₓ, Al₂O₃, HfO, TiO₂, and ZrO.

20. The semiconductor light emitting device package of claim 1, wherein the first conductivity-type and second conductivity-type semiconductor layers comprise a nitride semiconductor.

21. The semiconductor light emitting device package of claim 1, wherein the first and second electrodes comprise one or more of Ag, Al, Ni, Cr, Cu, Au, Pd, Pt, Sn, W, Rh, Ir, Ru, Mg, Zn, Ti, or an alloy thereof.

22. The method according to claim 2, wherein during the removing at least a portion of the growth substrate, the entire growth substrate is removed.

23. The method according to claim 2, wherein during the removing at least a portion of the support substrate, the entire support substrate is removed.

24. The method according to claim 2, wherein a substantially planar surface is formed as a result of the removing at least a portion of the support substrate.

25. The method according to claim 24, wherein the planar surface comprises a portion of the support substrate remaining after the removing at least a portion of the support substrate, and the first and second electrodes.

26. The method according to claim 2, wherein the support substrate is removed by a laser lift-off process, chemical-mechanical polishing, wet-etching, or dry etching.

27. The method according to claim 2, wherein the first electrode is formed by:
forming a via in the second conductivity-type semiconductor layer and the active layer exposing a surface of the first conductivity-type semiconductor layer;
forming an insulating layer on the via sidewall and on the first surface of the light emitting structure; and
filling the via with a conductive material.

28. The method according to claim 27, wherein the via is formed by etching the second conductivity-type semiconductor layer and the active layer.

29. The method according to claim 27, wherein the first electrode is substantially T-shaped.

30. The method according to claim 27, wherein the insulating layer is bounded by the first electrode.

31. The method according to claim 2, further comprising disposing a wavelength conversion layer on the light transmissive substrate before disposing the light transmissive substrate on the first conductivity-type semiconductor layer.

32. The method according to claim 2, further comprising disposing an adhesive layer on the light transmissive substrate before disposing the light transmissive substrate on the first conductivity-type semiconductor layer.

33. The method according to claim 32, further comprising a disposing a wavelength conversion layer between the light transmissive substrate and the adhesive layer.

34. The method according to claim 2, further comprising forming a plurality of first electrodes and second electrodes on the first surface.

35. The method according to claim 2, further comprising disposing a lens on the light transmissive substrate.

36. The method according to claim 35, wherein the lens is formed by:
depositing a resin on the light transmissive substrate; and
shaping the resin to form the lens using a stamp.

37. The method according to claim 2, wherein the light emitting structure comprises a plurality of nano-structures formed by:
forming a plurality of first conductivity-type semiconductor rods on the first conductivity-type layer;
disposing the active layer on the first conductivity-type semiconductor rods; and
disposing a second conductivity-type semiconductor layer on the active layer.

38. The method according to claim 37, further comprising disposing a filler material between the nano-structures.

39. The method according to claim 37, further comprising disposing an ohmic contact material on the second conductivity-type semiconductor layer.

40. The semiconductor light emitting device package of claim 3, further comprising a support substrate, wherein the support substrate, first electrode, and second electrode form a substantially planar surface.

41. The semiconductor light emitting device package of claim 3, wherein the insulating layer is bounded by the first electrode.

43. The semiconductor light emitting device package of claim 3, further comprising a wavelength conversion layer between the light transmissive substrate and the first conductivity-type semiconductor layer.

44. The semiconductor light emitting device package of claim 3, further comprising an adhesive layer between the wavelength conversion layer and the first conductivity-type semiconductor layer.

45. The semiconductor light emitting device package of claim 44, wherein the wavelength conversion layer comprises a phosphor.

46. The semiconductor light emitting device package of claim 3, further comprising a plurality of first electrodes and second electrodes disposed on the first surface.

47. The semiconductor light emitting device package of claim 3, wherein a surface of the light transmissive substrate opposite the surface of the light transmissive substrate facing the first conductivity-type semiconductor layer comprises a plurality of alternating protrusions and depressions.

47. The semiconductor light emitting device package of claim 3, further comprising a lens disposed on the light transmissive substrate.

48. The semiconductor light emitting device package of claim 47, wherein the lens is hemispherical-shaped.

49. The semiconductor light emitting device package of claim 47, wherein the lens is a Fresnel lens.

50. The semiconductor light emitting device package of claim 3, wherein the light emitting structure comprises a plurality of nano-structures comprising:
a plurality of first conductivity-type semiconductor rods disposed on the first conductivity-type layer;
the active layer disposed on the first conductivity-type semiconductor rods; and
the second conductivity-type semiconductor layer disposed on the active layer.

51. The semiconductor light emitting device package of claim 50, further comprising a filler material between the nano-structures.

52. The semiconductor light emitting device package of claim 50, further comprising an ohmic contact material on the second conductivity-type semiconductor layer.

53. The semiconductor light emitting device package of claim 3, wherein the first and second electrodes cover about 1% to about 5% of a total surface area of the first surface.

54. The semiconductor light emitting device package of claim 53, wherein the light transmissive layer comprises at least one of glass, quartz, transparent resin, SiO₂, SiNₓ, Al₂O₃, HfO, TiO₂, and ZrO.

55. The semiconductor light emitting device package of claim 3, wherein the first conductivity-type and second conductivity-type semiconductor layers comprise a nitride semiconductor.

56. The semiconductor light emitting device package of claim 3, wherein the first and second electrodes comprise one or more of Ag, Al, Ni, Cr, Cu, Au, Pd, Pt, Sn, W, Rh, Ir, Ru, Mg, Zn, Ti, or an alloy thereof.
